(19) United States
(12) Patent Application Publication
(10) Pub. No.: US 2007/0244664 A1
(43) Pub. Date: Oct. 18, 2007

(54) Resistance calculating method

(75) Inventor: Yu-Hsu Lin, San Jose, CA (US)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: Hon Hai Precision Industry Co., LTD.

(21) Appl. No.: 11/586,977

(22) Filed: Oct. 26, 2006

(30) Foreign Application Priority Data
Apr. 14, 2006 (CN) 200610060316.5

(51) Int. Cl. G06F 19/00; G01R 15/00; G01R 27/00

(52) U.S. Cl. 702/136; 702/1; 702/57; 702/127; 702/130; 702/189; 374/45; 703/13

(57) ABSTRACT

An exemplary resistance calculating method includes steps of: calculating a heat transfer rate of a conductor; and finding a resistance of the conductor as a reciprocal of the heat transfer rate of the conductor. The calculating method includes sub-steps of: simulating the conductor with a software which can calculates a heat transfer rate of the conductor according to a coefficient of heat conductivity of the conductor and a temperature difference of input and output terminals of the conductor; setting the coefficient of heat conductivity of the conductor with a reciprocal of a resistivity of a material of which the conductor comprises; setting the temperature difference of the input and output terminals with −1 Celsius degrees; and calculating the heat transfer rate of the simulated conductor with the software.

### BACKGROUND OF THE INVENTION

1. Field of the Invention

The present invention relates to calculating methods, and particularly to a resistance calculating method.

2. Description of Related Art

In electrical applications, a method for calculating resistance of a conductor uses the following equation:

$$\frac{1}{R} = {\int }_{V} \frac{1}{ρ} \frac{S}{L}$$

wherein R is the resistance of the conductor, ρ is a resistivity of a material of the conductor, S is a section area of the conductor, L is a length of the conductor, and V is a volume of the conductor.

The resistance of the conductor may also be found by using the following equation:

$$R = {\sum }_{i = 1}^{n} {ρ}_{i} \frac{{L}_{i}}{{S}_{i}}$$

wherein n is an integer. This method relies on dividing the conductor into n cuboid parts, and then measuring and adding the resistance of each part. However, each of the aforementioned methods cannot be used to calculate the resistance of the conductor, when the conductor is not of uniform shape or is made of composite materials.

What is needed, therefore, is a resistance calculating method which can solve the above problems.

### SUMMARY OF THE INVENTION

An exemplary resistance calculating method includes steps of: calculating a heat transfer rate of a conductor; and finding a resistance of the conductor as a reciprocal of the heat transfer rate of the conductor. The calculating method includes sub-steps of: simulating the conductor with a software which can calculates a heat transfer rate of the conductor according to a coefficient of heat conductivity of the conductor and a temperature difference of input and output terminals of the conductor; setting the coefficient of heat conductivity of the conductor with a reciprocal of a resistivity of a material of which the conductor comprises; setting the temperature difference of the input and output terminals with −1 Celsius degrees; and calculating the heat transfer rate of the simulated conductor with the software.

Other advantages and novel features will become more apparent from the following detailed description when taken in conjunction with the accompanying drawings, in which:

### BRIEF DESCRIPTION OF THE DRAWINGS

FIG. 1 is a flow diagram of one embodiment of a resistance calculating method in accordance with the present invention, the resistance calculating method includes a heat transfer rate calculating method; and

FIG. 2 is a flow diagram of the heat transfer rate calculating method of FIG. 1.

### DETAILED DESCRIPTION OF THE INVENTION

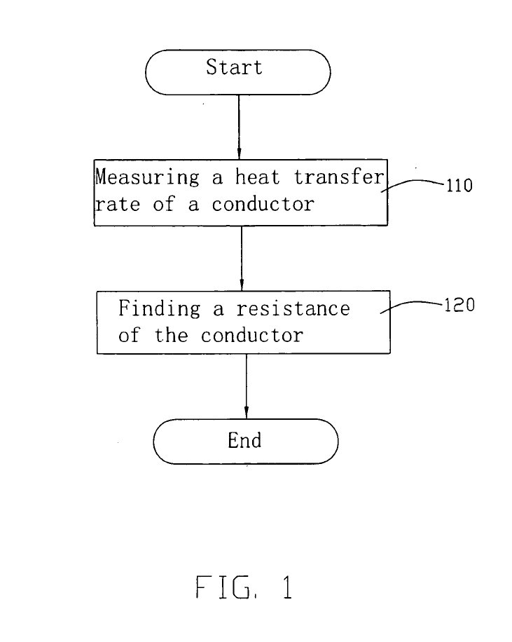

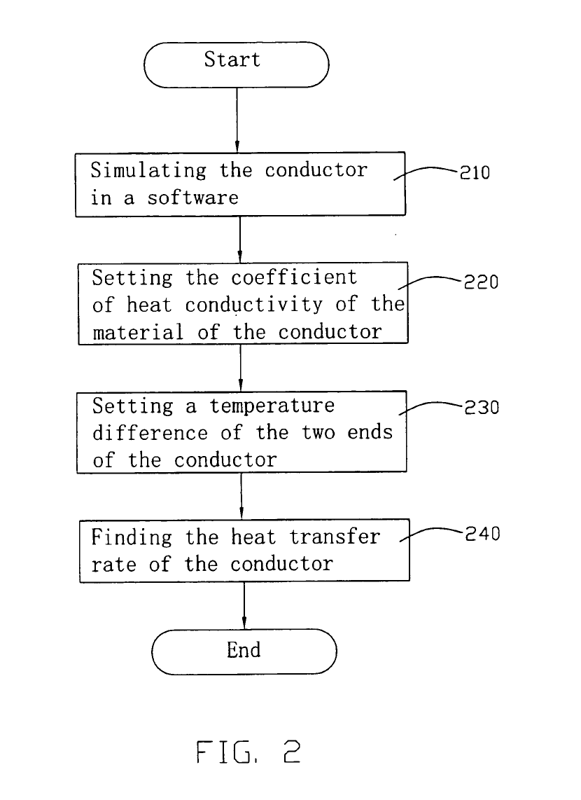

Referring to FIG. 1 and FIG. 2, a resistance calculating method in accordance with the present invention includes the following steps.

Step 110: calculating a heat transfer rate of a conductor using the following equation:

$$\frac{- Δ T}{} = {\int }_{V} K \frac{S}{L}$$

wherein [symbol] denotes a heat transfer rate of the conductor, ΔT denotes a temperature difference of the conductor, K denotes a coefficient of heat conductivity of material from which the conductor is made, S denotes a section area of the conductor, L denotes a length of the conductor, and V denotes a volume of the conductor, and setting the coefficient of heat conductivity K and the temperature difference ΔT of the conductor according to the follow equations:

$$K = \frac{1}{ρ} , Δ T = - 1$$

wherein ρ denotes a resistivity of the material of the conductor; and

Step 120: finding a resistance of the conductor, which is a reciprocal of the heat transfer rate of the conductor.

Referring also to FIG. 2, the calculating step 110 includes the following sub-steps.

Step 210: providing a Finite Element Analysis (FEA) software, and simulating the conductor in the FEA software which divides the conductor into a plurality of meshes;

Step 220: setting the coefficient of heat conductivity K of the conductor with the reciprocal of the resistivity ρ of the material of the conductor;

Step 230: taking an end of the simulated conductor as the input terminal and another end as the output terminal, and preferably setting the temperature at the output terminal to be zero Celsius degrees and the temperature at the input terminal to be one Celsius degrees, thereby the temperature difference ΔT is simulated as −1 Celsius degrees; and

Step 240: finding the heat transfer rate of the simulated conductor by use of the FEA software which is a sum of the heat transfer rate of the meshes.

The resistance calculating method finds the resistance of the conductor by finding the heat transfer rate of the simulated conductor under a certain condition.

It is believed that the present invention and its advantages will be understood from the foregoing description, and it will be apparent that various changes may be made thereto without departing from the spirit and scope of the invention or sacrificing all of its material advantages, the example hereinbefore described merely being a preferred or exemplary embodiment of the invention.

What is claimed is:

1. A resistance calculating method comprising steps of:
calculating a heat transfer rate of a conductor, the calculating method comprising the following sub-steps of:
simulating the conductor with a software which can calculate a heat transfer rate of the conductor according to a coefficient of heat conductivity of the conductor and a temperature difference of input and output terminals of the conductor;
setting the coefficient of heat conductivity of the conductor with a reciprocal of a resistivity of a material of which the conductor comprises;
setting the temperature difference of the input and output terminals with −1 Celsius degrees; and
calculating the heat transfer rate of the simulated conductor with the software; and
finding a resistance of the conductor as a reciprocal of the heat transfer rate of the simulated conductor.

2. The resistance calculating method as claimed in claim 1, wherein the software is a Finite Element Analysis software.

3. A method for calculating a resistance of a conductor, comprising steps of:
simulating the conductor with a software which can calculate a heat transfer rate of the conductor according to the following equation:
$$\frac{- Δ T}{} = {\int }_{V} K \frac{S}{L} ,$$
wherein [symbol] denotes the heat transfer rate of the conductor, ΔT denotes a temperature difference of two opposite ends of the conductor, K denotes a coefficient of heat conductivity of material from which the conductor is made, S denotes a section area of the conductor, L denotes a length of the conductor, and V denotes a volume of the conductor;
setting K with a reciprocal of a resistivity of the material of which the conductor is made;
setting ΔT with −1 Celsius degree, whereby the software calculating the heat transfer rate of the simulated conductor; and
determining the resistance of the conductor by forming a reciprocal of the heat transfer rate of the simulated conductor.

4. The method as claimed in claim 3, wherein the software is a Finite Element Analysis software.

5. A method for calculating a resistance of a conductor, comprising steps of:
simulating the conductor with a software which can achieve a value according to a first parameter and a second parameter;
setting the first parameter with a reciprocal of a resistivity of the material of which the conductor is made;
setting the second parameter with −1 Celsius degree whereby the software achieving the value; and
determining the resistance of the conductor by forming a reciprocal of the achieved value the simulated conductor.

6. The method as claimed in claim 5, wherein the software is a Finite Element Analysis software.
